(19) United States
(12) Patent Application Publication
(10) Pub. No.: US 2013/0009150 A1
(43) Pub. Date: Jan. 10, 2013

(54) SEMICONDUCTOR DEVICE, ELECTRONIC DEVICE, WIRING SUBSTRATE, MANUFACTURING METHOD OF SEMICONDUCTOR DEVICE, AND MANUFACTURING METHOD OF WIRING SUBSTRATE

(75) Inventors: Naoya INOUE, Kanagawa (JP); Kishou KANEKO, Kanagawa (JP); Yoshihiro HAYASHI, Kanagawa (JP)

(73) Assignee: RENESAS ELECTRONICS CORPORATION, Kanagawa (JP)

(21) Appl. No.: 13/540,637

(22) Filed: Jul. 3, 2012

(30) Foreign Application Priority Data
Jul. 6, 2011 (JP) 2011-150402

(51) Int. Cl. H01L 27/06; H01L 21/58; H01L 21/20; H01L 23/485

(52) U.S. Cl. 257/43; 257/296; 438/123; 438/479; 257/E27.016; 257/E21.505; 257/E21.09; 257/E23.019

(57) ABSTRACT

When a semiconductor element is formed over a wiring substrate, the number of manufacturing steps of the wiring substrate is reduced.

A first wiring 232 is disposed over one surface of a core layer 200. A semiconductor layer 236 is formed over the first wiring 232 and over one surface of the core layer 200 located around the first wiring 232. The first wiring 232 and the semiconductor layer 236 form a semiconductor element. In the present embodiment, the semiconductor element is a transistor 230, in which the first wiring 232 is the gate electrode, and has a gate insulating film 234 between the semiconductor layer 236 and the first wiring 232.

### CROSS-REFERENCE TO RELATED APPLICATION

The disclosure of Japanese Patent Application No. 2011-150402 filed on Jul. 6, 2011 including the specification, drawings and abstract is incorporated herein by reference in its entirety.

### BACKGROUND

The present invention relates to a semiconductor device in which a semiconductor chip is mounted over a wiring substrate, an electronic device, a wiring substrate, a manufacturing method of the semiconductor device, and a manufacturing method of the wiring substrate.

A semiconductor chip is used in a state in which the semiconductor chip is mounted over a wiring substrate. Examples of the wiring substrate include a resin interposer and a semiconductor interposer.

Japanese Patent Laid-Open No. 2007-287847 (Patent Document 1) describes that a circuit including a transistor and the like is formed over a semiconductor substrate of a semiconductor interposer.

On the other hand, there is a transistor made of a thin film of a compound semiconductor. For example, Japanese Patent Laid-Open No. 2007-96055 (Patent Document 2) and Japanese Patent Laid-Open No. 2007-123861 (Patent Document 3) describe that a thin film of a compound semiconductor is formed over a substrate and a transistor is formed using the thin film.

Further, Japanese Patent Laid-Open No. 2010-141230 (Patent Document 4) describes that a semiconductor layer is formed in wiring layers and a transistor is formed using the semiconductor layer and wiring of the wiring layer. In this transistor, wiring located below the semiconductor layer is used as a gate electrode and a diffusion prevention film between the wiring layers is used as a gate insulating film.

### SUMMARY

If elements such as transistors can be embedded in a wiring substrate, design freedom of a semiconductor device is improved. However, the method described in Patent Document 1 uses a semiconductor chip as a semiconductor interposer in practice. Therefore, the number of manufacturing steps of the interposer increases.

The present invention provides a semiconductor device including a wiring substrate and a semiconductor chip mounted over the wiring substrate. The wiring substrate includes a core layer, a first resin layer formed over the core layer, a first wiring formed over the core layer or over the first resin layer, and a semiconductor layer formed over a layer of the core layer and the first resin layer, over which the first wiring is formed, and over the first wiring. A semiconductor element is formed by the first wiring and the semiconductor layer.

The present invention provides a semiconductor device including a wiring substrate, and a semiconductor chip mounted over the wiring substrate. The wiring substrate includes a semiconductor substrate, a wiring layer formed over the semiconductor substrate, a first wiring formed over the wiring layer, and a semiconductor layer which is located over the wiring layer and which overlaps the first wiring in planar view. A semiconductor element is formed by the first wiring and the semiconductor layer.

The present invention provides an electronic device including a semiconductor device, and a circuit substrate over which the semiconductor device is mounted. The semiconductor device includes a wiring substrate, and a semiconductor chip mounted over the wiring substrate. The wiring substrate includes a core layer, a first resin layer formed over the core layer, a first wiring formed over the core layer or over the first resin layer, and a semiconductor layer formed over a layer of the core layer and the first resin layer, over which the first wiring is formed, and over the first wiring. A semiconductor element is formed by the first wiring and the semiconductor layer.

The present invention provides an electronic device including a semiconductor device, and a circuit substrate over which the semiconductor device is mounted. The semiconductor device includes a wiring substrate, and a semiconductor chip mounted over the wiring substrate. The wiring substrate includes a semiconductor substrate, a wiring layer formed over the semiconductor substrate, a first wiring formed over the wiring layer, and a semiconductor layer which is located over the wiring layer and which overlaps the first wiring in planar view. A semiconductor element is formed by the first wiring and the semiconductor layer.

The present invention provides a wiring substrate including a core layer, a first resin layer formed over the core layer, a first wiring formed over the core layer or over the first resin layer, and a semiconductor layer formed over a layer of the core layer and the first resin layer, over which the first wiring is formed, and over the first wiring. A semiconductor element is formed by the first wiring and the semiconductor layer.

The present invention provides a wiring substrate including a semiconductor substrate, a wiring layer formed over the semiconductor substrate, a first wiring formed in the wiring layer, and a semiconductor layer which is located over the wiring layer and which overlaps the first wiring in planar view. A semiconductor element is formed by the first wiring and the semiconductor layer.

The present invention provides a manufacturing method of a semiconductor device. The manufacturing method includes a step of mounting a semiconductor chip over a wiring substrate. The wiring substrate includes a core layer, a first resin layer formed over the core layer, a first wiring formed over the core layer or over the first resin layer, and a semiconductor layer formed over a layer of the core layer and the first resin layer, over which the first wiring is formed, and over the first wiring. A semiconductor element is formed by the first wiring and the semiconductor layer.

The present invention provides a manufacturing method of a semiconductor device. The manufacturing method includes a step of mounting a semiconductor chip over a wiring substrate. The wiring substrate includes a semiconductor substrate, a wiring layer formed over the semiconductor substrate, a first wiring formed over the wiring layer, and a semiconductor layer which is located over the wiring layer and which overlaps the first wiring in planar view. A semiconductor element is formed by the first wiring and the semiconductor layer.

The present invention provides a manufacturing method of a wiring substrate. The manufacturing method includes a step of forming a core layer, a step of forming a first resin layer over the core layer, further a step of forming a first wiring over the core layer or over the first resin layer, and a step of forming a semiconductor layer over a layer of the core layer and the first resin layer, over which the first wiring is formed, and over the first wiring. A semiconductor element is formed by the first wiring and the semiconductor layer.

The present invention provides a manufacturing method of a wiring substrate. The manufacturing method includes a step of forming a first wiring layer including a first wiring over a semiconductor substrate, and a step of forming a semiconductor layer that overlaps the first wiring in planar view over the first wiring layer. A semiconductor element is formed by the first wiring and the semiconductor layer.

According to the present invention, a semiconductor element is formed over the wiring layer of the wiring substrate. Therefore, compared with a case where a semiconductor element such as a transistor is formed over a semiconductor substrate, it is possible to reduce the number of manufacturing steps required to form the semiconductor element. Therefore, it is possible to reduce the number of manufacturing steps of the wiring substrate.

According to the present invention, when a semiconductor element is formed over a wiring substrate, the number of manufacturing steps of the wiring substrate can be reduced.

### BRIEF DESCRIPTION OF THE DRAWINGS

FIG. 1 is a diagram showing a configuration of an electronic device according to a first embodiment;

FIG. 2 is a cross-sectional view showing a configuration of a wiring substrate;

FIG. 3 is a plan view of a transistor shown in FIG. 2;

FIG. 4 is a first example of a circuit diagram of the electronic device shown in FIG. 1;

FIG. 5 is a second example of the circuit diagram of the electronic device shown in FIG. 1;

FIGS. 6A and 6B are cross-sectional views showing a forming method of the wiring substrate shown in FIG. 2;

FIGS. 7A and 7B are cross-sectional views showing a forming method of the wiring substrate shown in FIG. 2;

FIG. 8 is a circuit diagram showing a configuration of a semiconductor device according to a second embodiment;

FIG. 9 is a cross-sectional view showing a configuration of a wiring substrate according to a third embodiment;

FIG. 10 is a cross-sectional view showing a configuration of a wiring substrate according to a fourth embodiment;

FIG. 11 is a cross-sectional view showing a configuration of a wiring substrate according to a fifth embodiment;

FIG. 12 is a cross-sectional view showing a configuration of a wiring substrate according to a sixth embodiment;

FIG. 13 is a cross-sectional view showing a configuration of a wiring substrate according to a seventh embodiment;

FIG. 14 is a cross-sectional view showing a configuration of a wiring substrate according to an eighth embodiment;

FIG. 15 is a cross-sectional view showing a configuration of a wiring substrate according to a ninth embodiment;

FIG. 16 is a cross-sectional view showing a configuration of an electronic device according to a tenth embodiment;

FIG. 17 is a cross-sectional view showing a configuration of a wiring substrate according to an eleventh embodiment; and

FIG. 18 is a plan view of a transistor shown in FIG. 17.

### DETAILED DESCRIPTION

Hereinafter, embodiments of the present invention will be described with reference to the drawings. In all the drawings, the same or similar elements are denoted by the same reference numerals and the description thereof will be appropriately omitted.

### First Embodiment

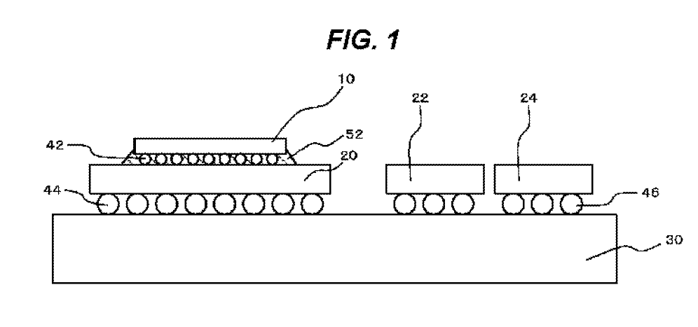

FIG. 1 is a diagram showing a configuration of an electronic device according to a first embodiment. The electronic device is a device in which a semiconductor device is mounted over a printed circuit board (circuit substrate) 30. The semiconductor device includes a wiring substrate 20 and a semiconductor chip 10. The semiconductor chip 10 is mounted over the wiring substrate 20. In the example shown in FIG. 1, the semiconductor chip 10 is flip-chip mounted over the wiring substrate 20 and coupled to the wiring substrate 20 through bumps 42. A coupling surface between the semiconductor chip 10 and the wiring substrate 20 is sealed with an underfill resin 52.

The semiconductor device is mounted over the printed circuit board 30 by using solder balls 44. Further, electronic components 22 and 24 are mounted over the printed circuit board 30 by using solder balls 46. The electronic components 22 and 24 are coupled to the semiconductor device including the semiconductor chip 10 and the wiring substrate 20 through wiring provided in the printed circuit board 30.

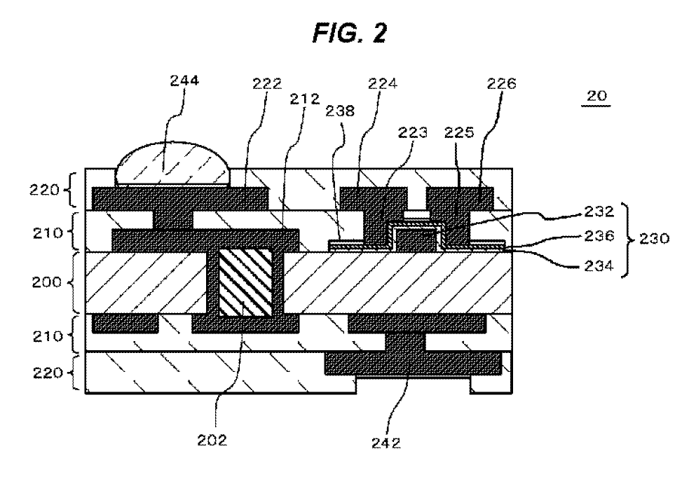

FIG. 2 is a cross-sectional view showing a configuration of the wiring substrate 20. In the present embodiment, the wiring substrate 20 is a resin interposer and has a core layer 200. The core layer 200 is formed of, for example, a material containing an epoxy resin as a main component. Resin layers (build-up layer) 210 and wirings 212 are formed on both surfaces of the core layer 200. A part of the wirings 212 on respective surfaces is coupled to each other via a through-hole provided in the core layer 200. An insulating material 202 is buried in a portion of the through-hole where metal is not provided.

A first wiring 232 is provided over one surface of the core layer 200. A semiconductor layer 236 is formed over the first wiring 232 and over one surface of the core layer 200 located around the first wiring 232. The first wiring 232 and the semiconductor layer 236 form a semiconductor element. In the present embodiment, the semiconductor element is a transistor 230, in which the first wiring 232 is the gate electrode, and has a gate insulating film 234 between the semiconductor layer 236 and the first wiring 232. The gate insulating film 234 and the semiconductor layer 236 are formed in areas around the first wiring 232 over the first wiring 232 and over the core layer 200.

The gate insulating film 234 is formed by, for example, an insulating film containing silicon such as SiO₂ film, SiON film, SiN film, SiCN film, and SiC film, or a metal oxide such as AlO, HfO, ZrO, and TaO, or an insulating film formed by mixing some insulating materials of the above materials. The thickness of the gate insulating film 234 is, for example, 5 nm or more and 100 nm or less.

The thickness of the semiconductor layer 236 is, for example, 5 nm or more and 200 nm or less. The semiconductor layer 236 includes, for example, an oxide semiconductor layer such as InGaZnO (IGZO) layer, InZnO layer, ZnO layer, ZnAlO layer, ZnCuO layer, NiO layer, SnO layer, and CuO layer. The semiconductor layer 236 may have a single layer structure of the oxide semiconductor layer described above or may have a laminated structure including the oxide semiconductor layer and other layers. An example of the laminated structure is a laminated film of IGZO/Al₂O₃/IGZO/Al₂O₃. The semiconductor layer 236 may be a polysilicon layer or an amorphous silicon layer.

A source and a drain are provided in the semiconductor layer 236. The source and drain are formed at least in a portion located over the core layer 200 in the semiconductor layer 236. When the semiconductor layer 236 is an oxide semiconductor layer, the source and drain are formed by, for example, introducing oxygen defect, but may be formed by introducing impurities. When the semiconductor layer 236 is a polysilicon layer or an amorphous silicon layer, the source and drain are formed by introducing impurities. The width of the source and drain is, for example, 50 nm or more and 10 μm or less.

A region sandwiched by the source and drain in the semiconductor layer 236 is a channel region. In planar view, the channel region overlaps the first wiring 232 and the gate insulating film 234.

A hard mask film 238 is provided over the semiconductor layer 236. The hard mask film 238 is used when the semiconductor layer 236 is selectively left by etching. Therefore, the hard mask film 238 and the semiconductor layer 236 have the same planar shape. The hard mask film 238 may be a material which has etching selectivity with respect to the semiconductor layer 236 and the gate insulating film 234. The hard mask film 238 is formed by, for example, an insulating film containing silicon such as SiO₂ film, SiON film, SiN film, SiCN film, or SiC film.

The resin layer 210 is formed over one surface of the core layer 200, over the wiring 212, and over the transistor 230. Vias are buried in the resin layer 210. An electrode 222, a source wiring 224 (second wiring), and a drain wiring 226 (second wiring) are formed over the resin layer 210. The electrode 222 is coupled to the wiring 212. The source wiring 224 is coupled to the source of the transistor 230 through the via 223. The drain wiring 226 is coupled to the drain of the transistor 230 through the via 225.

A solder resist layer 220 is formed over the resin layer 210, over the source wiring 224, and over the drain wiring 226. An opening located over the electrode 222 is formed in the solder resist layer 220. In the opening, a solder pre-coat film 244 coupled to the electrode 222 is formed. The source wiring 224 is provided to couple to the bump 42 (shown in FIG. 1) of the semiconductor chip 10. In the present embodiment, the transistor 230 is provided on a surface of the core layer 200 facing the semiconductor chip 10.

The resin layer 210 and the solder resist layer 220 are formed also on the other surface side of the core layer 200. An electrode 242 is formed over the resin layer 210 on the other surface side. The solder resist layer 220 on the other surface side has an opening located over the electrode 242. The electrode 242 is an electrode to be coupled to the solder ball 44 (shown in FIG. 1).

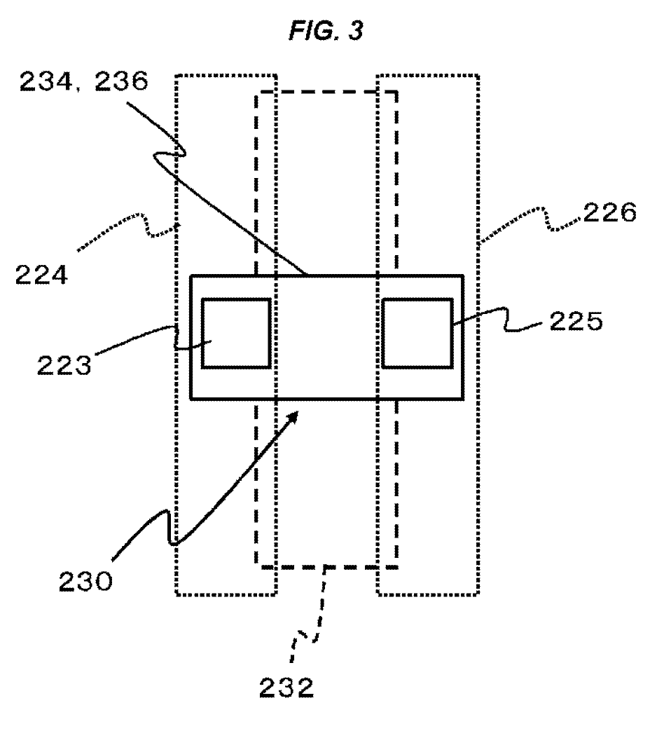

FIG. 3 is a plan view of the transistor 230 shown in FIG. 2. In the example shown in FIG. 3, a region in which one transistor 230 is formed in the semiconductor layer 236 has a rectangular shape. Vias 223 and 225 are coupled to portions near two short sides of the semiconductor layer 236.

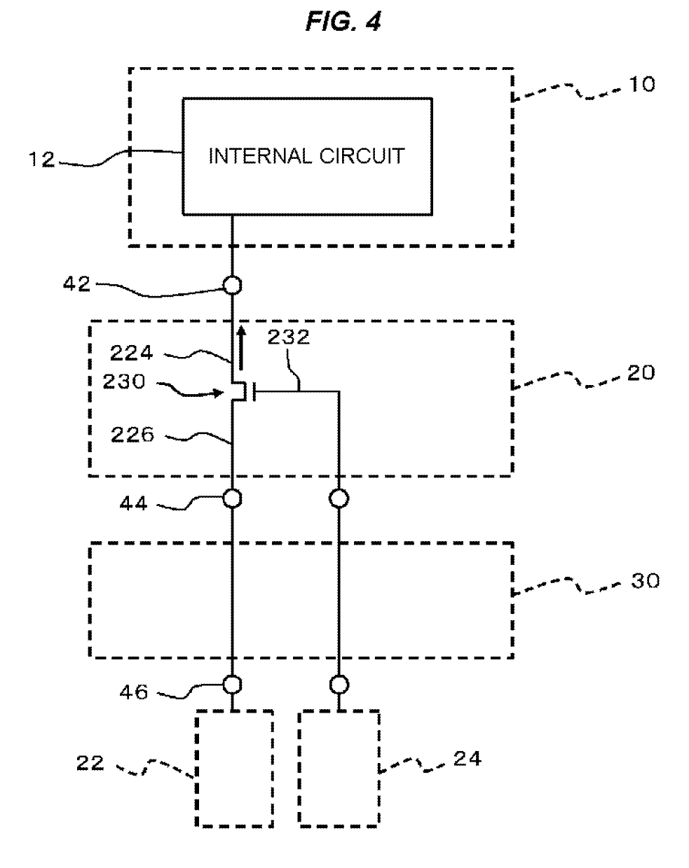

FIG. 4 is a first example of a circuit diagram of the electronic device shown in FIG. 1. In the example shown in FIG. 4, an internal circuit 12 of the semiconductor chip 10 is coupled to the source wiring 224 of the wiring substrate 20 through the bump 42. Thus, the internal circuit 12 is coupled to the source of the transistor 230 included in the wiring substrate 20.

The drain wiring 226 of the wiring substrate 20 is coupled to the printed circuit board 30 through the solder balls 44. In the example shown in FIG. 4, the drain wiring 226 is coupled to the electronic component 22 through the solder ball 44, the wiring included in the printed circuit board 30, and the solder ball 46. Thus, the drain of the transistor 230 is coupled to the electronic component 22.

The first wiring 232 of the transistor 230 is coupled to the electronic component 24 through the solder ball 44, the wiring included in the printed circuit board 30, and the solder ball 46. Thus, the gate electrode of the transistor 230 is coupled to the electronic component 24.

In the example shown in FIG. 4, the electronic component 24 has a function to generate a signal and the electronic component 22 has a function to generate a power supply voltage. The voltage of the signal generated by the electronic component 24 is higher than the power supply voltage generated by the electronic component 22. In other words, the transistor 230 is an element for converting the voltage of the signal generated by the electronic component 24 into the voltage generated by the electronic component 22.

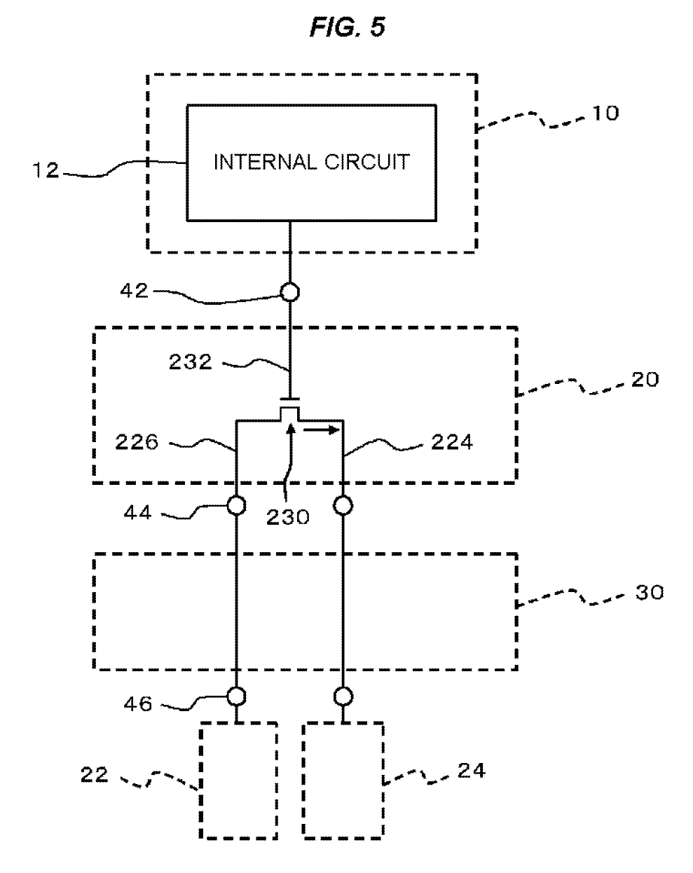

FIG. 5 is a second example of the circuit diagram of the electronic device shown in FIG. 1. In the example shown in FIG. 5, the internal circuit 12 of the semiconductor chip 10 is coupled to the first wiring 232 of the wiring substrate 20, that is, the gate electrode of the transistor 230, through the bump 42. The drain wiring 226 is coupled to the electronic component 22 through the solder ball 44, the wiring in the printed circuit board 30, and the solder ball 46. The source wiring 224 is coupled to the electronic component 24 through the solder ball 44, the wiring in the printed circuit board 30, and the solder ball 46.

In the example shown in FIG. 5, the electronic component 24 is a component into which a signal is inputted and the electronic component 22 is a component which generates a power supply voltage. The power supply voltage generated by the electronic component 22 is higher than a voltage of a signal outputted by the internal circuit 12. A voltage of a signal processed by the electronic component 24 is higher than the voltage of the signal outputted by the internal circuit 12 of the semiconductor chip 10. In other words, the transistor 230 is an element for converting the signal outputted by the internal circuit 12 into a signal having the voltage generated by the electronic component 22.

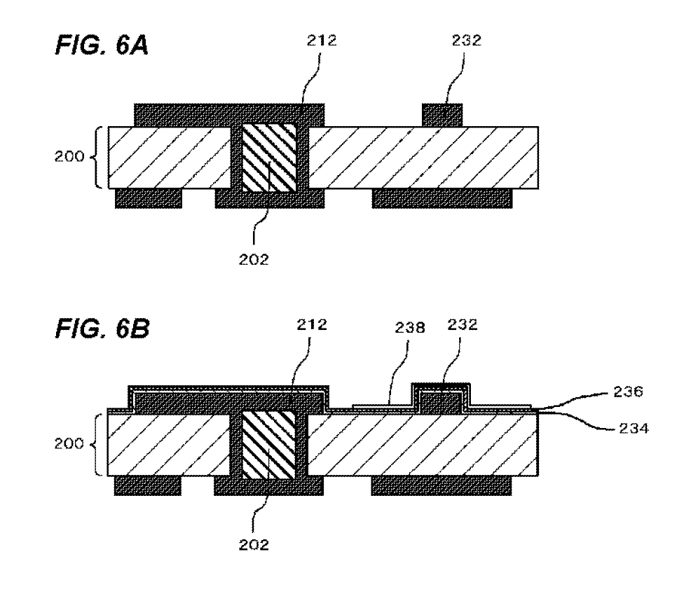

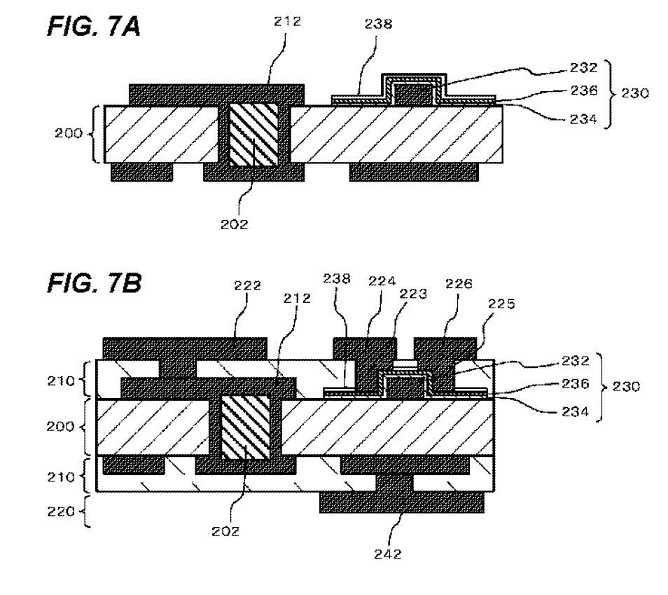

FIGS. 6A and 6B and FIGS. 7A and 7B are cross-sectional views showing a forming method of the wiring substrate 20 shown in FIG. 2. As shown in FIG. 6A, a through-hole is formed in the core layer 200 by using a drill or the like. Next, a plating film (for example, a copper film) is formed on both surfaces of the core layer 200 and an inner surface of the through-hole by using an electroless plating method. Next, the through-hole in the core layer 200 is filled with the insulating material 202. Next, electroplating is performed by using the plating film as a seed. Thereby, a plating film (for example, a copper film) grows over both surfaces of the core layer 200 and over the insulating material 202. Next, the plating film is selectively removed. Thereby, the wiring 212 and the first wiring 232 are formed.

Next, as shown in FIG. 6B, the gate insulating film 234 is formed over one surface of the core layer 200 and over the wiring 212 and the first wiring 232 over the one surface by using, for example, a CVD method. Next, the semiconductor layer 236 is formed over the gate insulating film 234. When the semiconductor layer 236 includes an oxide semiconductor layer such as InGaZnO, InZnO, ZnO, ZnAlO, ZnCuO, NiO, SnO, or CuO, the semiconductor layer 236 is formed by, for example, a sputtering method. At this time, the core layer 200 is heated to a temperature of 300° C. or less. When the semiconductor layer 236 is a polysilicon layer or an amorphous silicon layer, the semiconductor layer 236 is formed by, for example, a plasma CVD method.

Next, an insulating film to be the hard mask film 238 is formed over the semiconductor layer 236. Next, a resist pattern (not shown in the drawings) is formed over the insulating film and the insulating film is etched by using the resist pattern as a mask. Thereby, the hard mask film 238 is formed. Thereafter, the resist pattern is removed as needed.

Next, as shown in FIG. 7A, the semiconductor layer 236 and the gate insulating film 234 are etched by using the hard mask film 238 as a mask. Thereby, the semiconductor layer 236 and the gate insulating film 234 are formed into a desired pattern.

Next, as shown in FIG. 7B, the resin layers 210 are formed on both surfaces of the core layer 200. Next, a through-hole is formed in each of the two resin layers 210. Next, a plating film (for example, a copper film) is formed on a bottom surface and an inner surface of the through-hole and over the resin layers 210 by using an electroless plating method. Next, a resist pattern is formed over the plating film. Next, electroplating is performed by using the plating film as a seed. Thereby, a plating film (for example, a copper film) grows in regions of the plating films which are not covered with the resist pattern. Thereafter, the resist pattern is removed, and further the electroless plating film located below the resist pattern is removed. Thereby, the vias 223 and 225, the electrode 222, the source wiring 224, the drain wiring 226, and the electrode 242 are formed.

Thereafter, the solder resist layers 220 are formed over the resin layers 210. Next, the solder resist layers 220 are exposed and developed. Thereby, openings are formed in regions located over the electrode 222 and over the electrode 242 in the solder resist layers 220. Next, a seed metal film, for example, an NiAu film, is formed over the electrode 222 and over the electrode 242 by performing electroless plating. Next, the solder pre-coat film 244 is formed over the seed metal film of the electrode 222. In this way, the wiring substrate 20 shown in FIG. 2 is formed.

When the semiconductor chip 10 is mounted over the wiring substrate 20 formed as described above, the semiconductor device is formed. The semiconductor device, the electronic component 22, and the electronic component 24 are mounted over the printed circuit board 30, so that the electronic device shown in FIG. 1 is formed.

Next, functions and effects of the present embodiment will be described. According to the present embodiment, the transistor 230 is provided in the wiring substrate 20, which is a resin interposer. Therefore, compared with a case where a Si substrate in which a transistor and a multilayer wiring layer are formed is used as an interposer, it is possible to reduce the number of manufacturing steps. Therefore, the manufacturing cost of the wiring substrate 20 including a semiconductor element can be reduced.

The transistor 230 is formed over the core layer 200, so that the transistor 230 can be formed more easily than a case in which the transistor 230 is formed over the resin layer 210. The transistor 230 is formed on the surface of the core layer 200, which faces the semiconductor chip 10. Therefore, it is possible to shorten the length of wiring between the semiconductor chip 10 and the transistor 230.

If it is desired to shorten the length of wiring from the electrode 242 to the transistor 230, it is suitable that the transistor 230 is formed on the surface on the electrode 242 side in the core layer 200.

### Second Embodiment

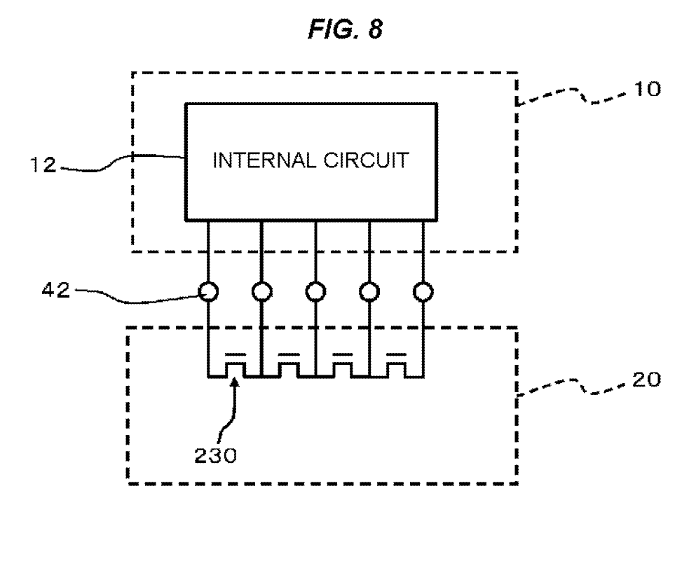

FIG. 8 is a circuit diagram showing a configuration of a semiconductor device according to a second embodiment. The semiconductor device according to the present embodiment includes the semiconductor chip 10 and the wiring substrate 20 and has the same configuration as that of the semiconductor device according to the first embodiment except for the points described below.

First, a plurality of transistors 230 is formed in the wiring substrate 20. Each of the sources and drains of the transistors 230 is coupled to the internal circuit 12 of the semiconductor chip 10 through the bump 42. The transistors 230 of the present embodiment are switching elements for switching functions of the internal circuit 12.

Also in the present embodiment, the same effects as those of the first embodiment can be obtained.

### Third Embodiment

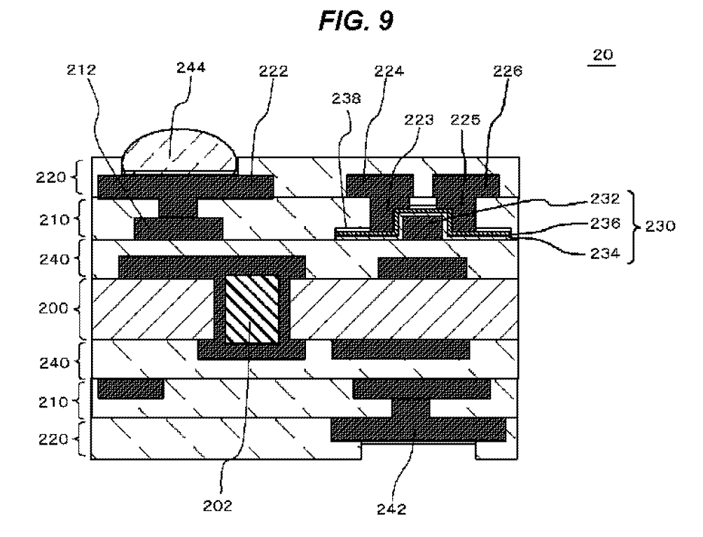

FIG. 9 is a cross-sectional view showing a configuration of a wiring substrate 20 according to a third embodiment. FIG. 9 corresponds to FIG. 2 in the first embodiment. An electronic device according to the present embodiment has the same configuration as that of the electronic device according to the first or second embodiment except for the configuration of the wiring substrate 20.

In the present embodiment, a resin layer 240 (a first resin layer: build-up layer) and a resin layer 210 (a second resin layer) are formed over the core layer 200. The wiring 212, the first wiring 232, the gate insulating film 234, the semiconductor layer 236, and the hard mask film 238 are formed over the resin layer 240. Thus, in the present embodiment, the transistor 230 is formed over the resin layer 240.

In this way, the transistor 230 may be formed in any one of the layers that form the wiring substrate 20. For example, in the present embodiment, a plurality of resin layers 240 may be formed between the resin layer 210 and the core layer 200.

Also in the present embodiment, compared with a case where a Si substrate in which a transistor and a multilayer wiring layer are formed is used as an interposer, it is possible to reduce the number of manufacturing steps. Therefore, the manufacturing cost of the wiring substrate 20 can be reduced. The transistor 230 is formed on the side facing the semiconductor chip 10 with respect to the core layer 200. Therefore, it is possible to shorten the length of wiring between the semiconductor chip 10 and the transistor 230.

### Fourth Embodiment

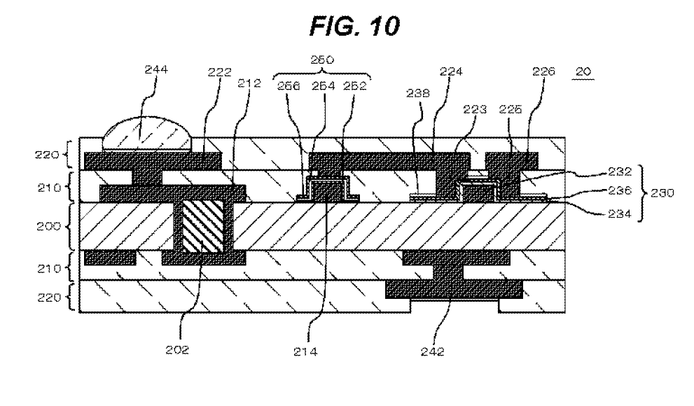

FIG. 10 is a cross-sectional view showing a configuration of a wiring substrate 20 according to a fourth embodiment. FIG. 10 corresponds to FIG. 2 in the first embodiment. An electronic device according to the present embodiment has the same configuration as that of the electronic device according to any one of the first to third embodiments except for the configuration of the wiring substrate 20. FIG. 10 shows the same case as that of the first embodiment.

In the present embodiment, the wiring substrate 20 has the same configuration as that of the wiring substrate 20 according to the first or third embodiment except for that the wiring substrate 20 of the present embodiment includes a storage element 250. The storage element 250 is formed in the same layer as the transistor 230 and coupled to the transistor 230 through the source wiring 224. In other words, in the present embodiment, the transistor 230 controls reading and writing of the storage element 250. For example, the storage element 250 stores data for switching circuits in the internal circuit 12 of the semiconductor chip 10 in the second embodiment.

In the present embodiment, the storage element 250 has a laminated structure in which a first layer 252 which is a conductive layer, a second layer 254 which is an insulating layer, and a third layer 256 which is a conductive layer are laminated in this order. This laminated structure is formed over the wiring 214 and over the core layer 200 located around the wiring 214. The wiring 214 is coupled to the first layer 252 and the via 223 is coupled to the third layer 256.

When the storage element 250 is a normal capacitive element (DRAM), the first layer 252 and the third layer 256 are formed of any one of or a laminated film of two or more of Ti layer, TiN layer, Ta layer, TaN layer, W layer, WN layer, Al layer, Cu layer, Ru layer, Pt layer, Ir layer, RuO layer, and IrO layer. The thickness of the first layer 252 and the third layer 256 is, for example, 50 nm or more and 500 nm or less. The second layer 254 is formed of any one of or a laminated film of two or more of SiN layer, SiO₂ layer, TaO layer, ZrO layer, HfO layer, and AlO layer. The thickness of the second layer 254 is, for example, 5 nm or more and 50 nm or less.

When the storage element 250 is a ferroelectric capacitive element (FeRAM), the first layer 252 and the third layer 256 are formed of any one of or a laminated film of two or more of Pt layer, Ir layer, IrO layer, Ru layer, RuO layer, TiN layer, and TaN layer. The thickness of the first layer 252 and the third layer 256 is, for example, 50 nm or more and 500 nm or less. The second layer 254 is formed of any one of or a laminated film of two or more of PbTiO₃, PbZrO₃, SrBi₂Ta₂O₉, and (Ba,Sr)TiO. The thickness of the second layer 254 is, for example, 50 nm or more and 200 nm or less.

When the storage element 250 is a resistance change element (ReRAM), the first layer 252 and the third layer 256 are formed of any one of or a laminated film of two or more of Ti layer, TiN layer, Ta layer, TaN layer, W layer, WN layer, Cu layer, Al layer, Pt layer, Ru layer, RuO layer, Ir layer, and IrO layer. The thickness of the first layer 252 and the third layer 256 is, for example, 10 nm or more and 500 nm or less. The second layer 254 is formed of any one of or a laminated film of two or more of TaO layer, ZrO layer, HfO layer, AlO layer, SiO₂ layer, and SiOCH layer. The thickness of the second layer 254 is, for example, 5 nm or more and 50 nm or less.

When the storage element 250 is a magnetic tunnel junction element (MRAM), the first layer 252 and the third layer 256 are formed of any one of Pt layer, Co layer, Ru layer, Ni layer, and Fe layer, or formed of a layer of mixture of some of these layers, or formed of a laminated film of two or more of these layers. The thickness of the first layer 252 and the third layer 256 is, for example, 3 nm or more and 50 nm or less. The second layer 254 is formed of any one of or a laminated film of two or more of AlO layer, MgO layer, SiO₂ layer, HfO layer, and ZrO layer. The thickness of the second layer 254 is, for example, 1 nm or more and 20 nm or less.

The forming method of the storage element 250 is the same as that of the transistor 230. Specifically, the first layer 252, the second layer 254, and the third layer 256 are laminated in this order over the core layer 200, the wiring 212, and the wiring 214. Next, a mask pattern (not shown in the figure) is formed over the first layer 252, the second layer 254, and the third layer 256 over the wiring 214 and the first layer 252, the second layer 254, and the third layer 256 are etched over the wiring 214 by using the mask pattern as a mask. Thereby, the storage element 250 is formed. Which of the storage element 250 and the transistor 230 is formed earlier over the core layer 200 doesn't matter.

Also in the present embodiment, the same effects as those of the first embodiment can be obtained. A memory cell including the transistor 230 and the storage element 250 can be provided in the wiring substrate 20.

### Fifth Embodiment

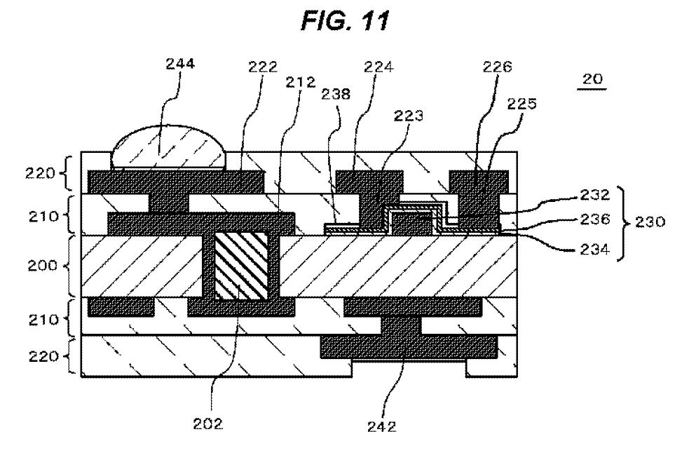

FIG. 11 is a cross-sectional view showing a configuration of a wiring substrate 20 according to a fifth embodiment. FIG. 11 corresponds to FIG. 2 in the first embodiment. An electronic device according to the present embodiment has the same configuration as that of the electronic device according to anyone of the first to fourth embodiments except for the configuration of the wiring substrate 20. FIG. 11 shows the same case as that of the first embodiment.

The wiring substrate 20 according to the present embodiment has the same configuration as that of the wiring substrate 20 according to any one of the first to third embodiments except for a point that the distance from the drain and via 225 of the transistor 230 to the first wiring 232 (gate electrode) is larger than the distance from the source and the via 223 to the first wiring 232.

Also in the present embodiment, the same effects as those of the first embodiment can be obtained. Also, it is possible to prevent insulation breakdown from occurring between the via 225 and the first wiring 232 even when a high voltage is applied to the drain of the transistor 230 like the circuit shown in FIG. 4 in the first embodiment. Thus, a high voltage can be applied to the drain of the transistor 230.

### Sixth Embodiment

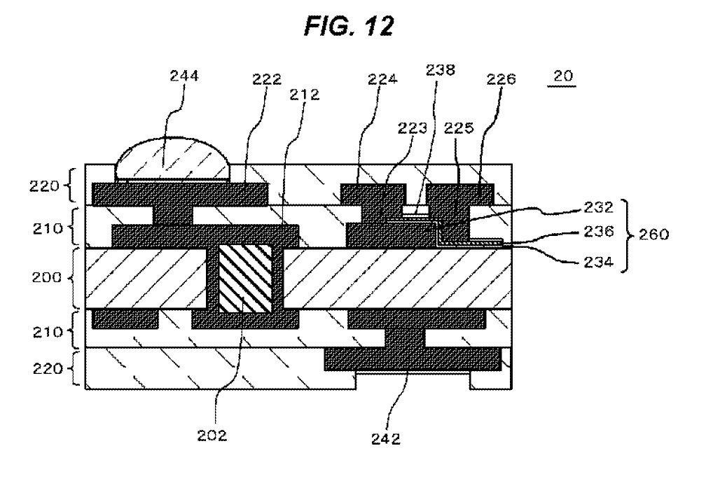

FIG. 12 is a cross-sectional view showing a configuration of a wiring substrate 20 according to a sixth embodiment. FIG. 12 corresponds to FIG. 2 in the first embodiment. An electronic device according to the present embodiment has the same configuration as that of the electronic device according to the first or third embodiment except for the configuration of the wiring substrate 20. FIG. 12 shows the same case as that of the first embodiment.

The wiring substrate 20 according to the present embodiment has the same configuration as that of the wiring substrate 20 according to any one of the first to third embodiments except for a point that the wiring substrate 20 according to the present embodiment includes a diode 260 instead of the transistor 230. The diode 260 has a structure which is formed by changing the structure of the transistor 230 of the first embodiment and in which the first wiring 232 is coupled to the source of the semiconductor layer 236 through the via 223.

According to the present embodiment, the diode 260 can be formed in the wiring substrate 20.

### Seventh Embodiment

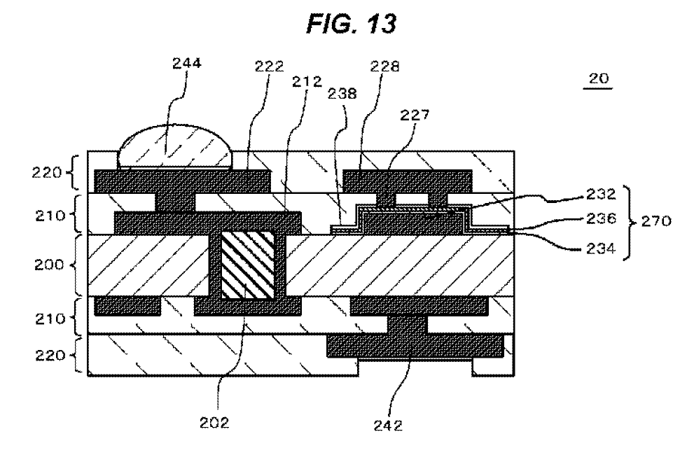

FIG. 13 is a cross-sectional view showing a configuration of a wiring substrate 20 according to a seventh embodiment. FIG. 13 corresponds to FIG. 2 in the first embodiment. An electronic device according to the present embodiment has the same configuration as that of the electronic device according to the first or third embodiment except for the configuration of the wiring substrate 20. FIG. 13 shows the same case as that of the first embodiment.

The wiring substrate 20 according to the present embodiment has the same configuration as that of the wiring substrate 20 according to any one of the first to third embodiments except for a point that the wiring substrate 20 according to the present embodiment includes an MIM type capacitive element 270 instead of the transistor 230. The capacitive element 270 has a configuration in which the first wiring 232 is a lower electrode, the gate insulating film 234 is a dielectric film, and the semiconductor layer 236 is an upper electrode.

According to the present embodiment, the MIM type capacitive element 270 can be formed in the wiring substrate 20.

### Eighth Embodiment

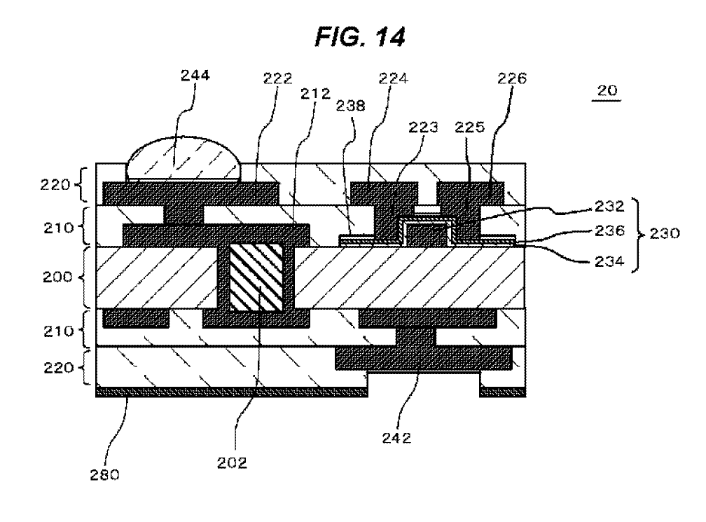

FIG. 14 is a cross-sectional view showing a configuration of a wiring substrate 20 according to an eighth embodiment. FIG. 14 corresponds to FIG. 2 in the first embodiment. An electronic device according to the present embodiment has the same configuration as that of the electronic device according to any one of the first to seventh embodiments except for the configuration of the wiring substrate 20. FIG. 14 shows the same case as that of the first embodiment.

The wiring substrate 20 according to the present embodiment has the same configuration as that of the wiring substrate 20 according to any one of the first to seventh embodiments except for a point that the wiring substrate 20 according to the present embodiment includes a heat radiation layer 280 in the surface having the electrode 242. The heat radiation layer 280 is, for example, a metal layer such as copper or aluminum. The thickness of the heat radiation layer 280 is, for example, 1 μm or more and 100 μm or less.

Also in the present embodiment, the same effects as those of the first to seventh embodiments can be obtained. Since the heat radiation layer 280 is provided, it is possible to efficiently radiate the heat generated by the transistor 230.

### Ninth Embodiment

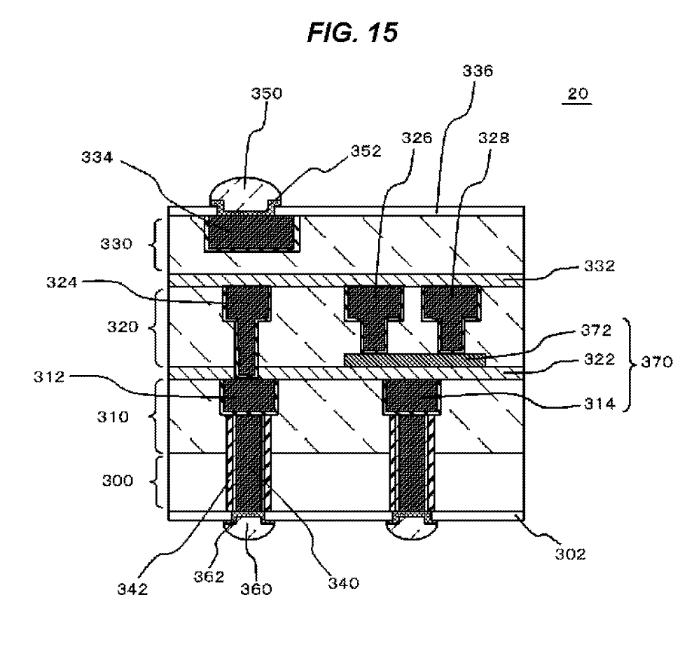

FIG. 15 is a cross-sectional view showing a configuration of a wiring substrate 20 according to a ninth embodiment. FIG. 15 corresponds to FIG. 2 in the first embodiment. An electronic device according to the present embodiment has the same configuration as that of the electronic device according to anyone of the first to eighth embodiments except for the configuration of the wiring substrate 20. FIG. 15 shows the same case as that of the first embodiment.

In the present embodiment, the wiring substrate 20 is a resin interposer using a semiconductor substrate (for example, a silicon substrate) 300. Specifically, the wiring substrate 20 has a multilayer wiring layer over the semiconductor substrate 300. The wiring layers have a configuration in which copper wiring is buried in a surface layer of an insulating layer. In the example shown in FIG. 15, a wiring layer 310, a wiring layer 320, and a wiring layer 330 are laminated in this order. A wiring 312 and a first wiring 314 are buried in the wiring layer 310. The wiring 312 and the first wiring 314 are formed in the same step. Therefore, the wiring 312 and the first wiring 314 have the same depth. A wiring 324, a source wiring 326, and a drain wiring 328 are buried in the wiring layer 320. A wiring 334 is buried in the uppermost wiring layer 330. A part of the wiring 334 forms an electrode, and a bump 350 is formed over the electrode through a barrier metal 352.

Each wiring described above may be formed by a dual damascene method or by a single damascene method. A barrier metal film is formed on side walls of a groove or a hole in which each wiring and via are buried. The barrier metal film is formed of, for example, Ti, Ta, Ru, W, or nitride or oxide of these metals. The barrier metal film may be a single layer formed of these materials or a laminated layer in which two or more layers are laminated. Examples of the laminated structure include TiN (upper layer)/Ti (lower layer) and Ta (upper layer)/TaN (lower layer).

A penetrating electrode 340 is formed in the semiconductor substrate 300. The penetrating electrode 340 penetrates the semiconductor substrate 300 and the wiring layer 310 and one end thereof is coupled to the wiring 312 or the first wiring 314. An insulating film 342 is formed on an inner wall of a hole in which the penetrating electrode 340 is buried. In other words, the penetrating electrode 340 is formed by forming the insulating film 342 on the inner wall of the hole penetrating the semiconductor substrate 300 and the wiring layer 310 and further burying a barrier metal and a metal such as copper in the hole.

A bump 360 is coupled to the other end of the penetrating electrode 340 through a barrier metal 362. The bump 360 is coupled to the wiring 312 or the first wiring 314 through the penetrating electrode 340. The rear surface of the semiconductor substrate 300 is covered with a protective insulating film 302.

A diffusion prevention film 322 is formed between the wiring layer 310 and the wiring layer 320. The diffusion prevention film 322 is formed of an insulating material including at least two types of elements out of Si, C, and N. For example, the diffusion prevention film 322 is SiN film, SiCN film, or SiC film. The diffusion prevention film 322 may be a laminated film in which at least two of the above films are laminated. The thickness of the diffusion prevention film 322 is, for example, 10 nm or more and 200 nm or less.

A semiconductor layer 372 is formed over a region where the first wiring 314 overlaps the diffusion prevention film 322 in planar view and areas around the region. The thickness of the semiconductor layer 372 is, for example, 10 nm or more and 200 nm or less. The semiconductor layer 372 includes, for example, an oxide semiconductor layer such as an InGaZnO (IGZO) layer, InZnO layer, ZnO layer, ZnAlO layer, ZnCuO layer, NiO layer, SnO layer, and CuO layer. The semiconductor layer 372 may have a single layer structure of the oxide semiconductor layer described above or may have a laminated structure including the oxide semiconductor layer and other layers. An example of the laminated structure is a laminated film of IGZO/Al₂O₃/IGZO/Al₂O₃. The semiconductor layer 372 may be a polysilicon layer or an amorphous silicon layer.

A source and a drain are provided in the semiconductor layer 372. When the semiconductor layer 372 is an oxide semiconductor layer, the source and drain are formed by, for example, introducing oxygen defect, but may be formed by introducing impurities. When the semiconductor layer 372 is a polysilicon layer or an amorphous silicon layer, the source and drain are formed by introducing impurities. The width of the source and drain is, for example, 50 nm or more and 1 μm or less. The source of the semiconductor layer 372 is coupled to a source wiring 326 through a via and the drain is coupled to a drain wiring 328 through a via.

A region sandwiched by the source and drain in the semiconductor layer 372 is a channel region. In planar view, the channel region overlaps the first wiring 314.

The first wiring 314, the diffusion prevention film 322, and the semiconductor layer 372 form a transistor 370. In other words, in the present embodiment, the transistor 370 is formed in the multilayer wiring layer of the wiring substrate 20. Specifically, the first wiring 314 is a gate electrode and the diffusion prevention film 322 is a gate insulating film. In the diffusion prevention film 322, a region where the first wiring 314 overlaps the diffusion prevention film 322 and areas around the region may be thinner than other regions.

The manufacturing method of the wiring substrate 20 according to the present embodiment is as follows. First, the wiring layer 310 is formed over the semiconductor substrate 300. Next, the wiring 312 and the first wiring 314 are buried in the wiring layer 310. Next, the diffusion prevention film 322 is formed over the wiring layer 310, the wiring 312, and the first wiring 314.

Next, the semiconductor layer 372 is formed over the diffusion prevention film 322. The forming method of the semiconductor layer 372 is the same as that of the semiconductor layer 236. Next, a hard mask film (not shown in the figure) is formed over the semiconductor layer 372 and the semiconductor layer 372 is patterned through the hard mask film. The hard mask includes, for example, the same material as that of the diffusion prevention film 322.

Next, the wiring layer 320 is formed over the diffusion prevention film 322 and the semiconductor layer 372. Next, a wiring groove and vias are formed in the wiring layer 320. Next, in regions exposed in the bottom surfaces of the via holes on the semiconductor layer 372, a process by reducing plasma (example: hydrogen plasma) or a process by nitrogen-containing plasma (example: ammonia plasma) is performed. Thereby, the source and drain are formed on the semiconductor layer 372.

Next, a via and wiring 324, the source wiring 326, and the drain wiring 328 are buried in the wiring layer 320. Next, the diffusion prevention film 332, the wiring layer 330, and the wiring 334 are formed.

Next, a hole for forming the penetrating electrode 340 is formed in the semiconductor substrate 300 and the wiring layer 310. Next, the insulating film 342, the barrier metal, and the penetrating electrode 340 are formed in the hole.

Next, the protective insulating films 336 and 302 are formed, and thereafter the barrier metal 352, the bump 350, the barrier metal 362, and the bump 360 are formed.

Also in the present embodiment, the same effects as those of the first embodiment can be obtained. Since a semiconductor interposer is used as the wiring substrate 20, it is possible to form the semiconductor layer 372 at a temperature higher than that in the first embodiment. Therefore, the characteristics of the transistor 370 can be improved. Since the thermal conductivity of semiconductor is higher than that of resin, it is possible to easily radiate the heat generated by the transistor 370.

### Tenth Embodiment

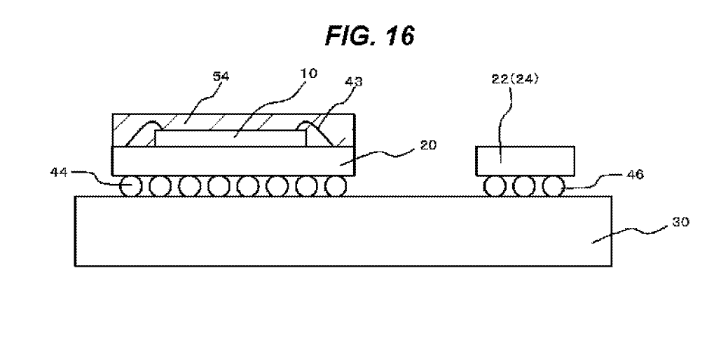

FIG. 16 is a cross-sectional view showing a configuration of an electronic device according to a tenth embodiment. FIG. 16 corresponds to FIG. 1 in the first embodiment. The electronic device according to the present embodiment has the same configuration as that of the electronic device according to the first embodiment except for a point that the semiconductor chip 10 is mounted in the wiring substrate 20 by using bonding wires 43. Also in the electronic devices according to the second to ninth embodiments, the semiconductor chip 10 may be mounted in the wiring substrate 20 by using the bonding wires 43.

Also in the present embodiment, the same effects as those of the first embodiment can be obtained.

### Eleventh Embodiment

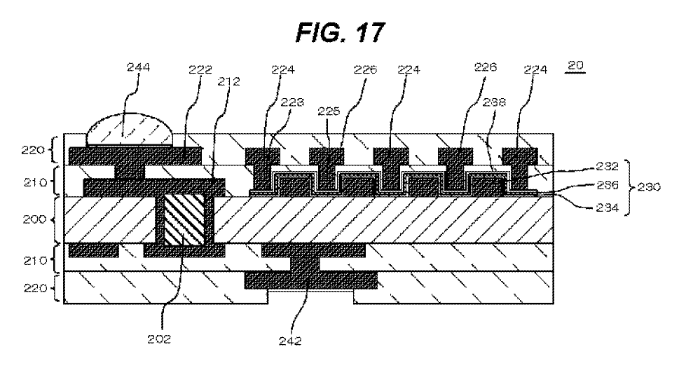

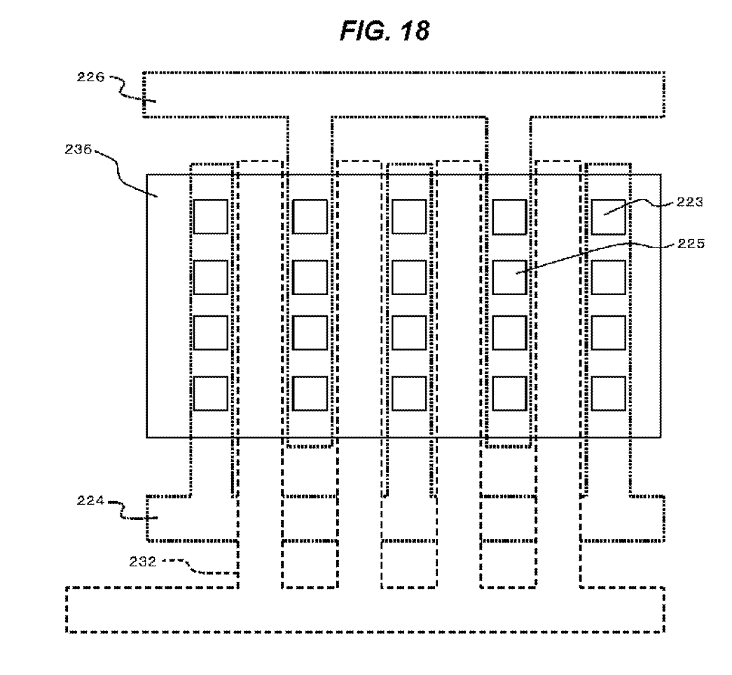

FIG. 17 is a cross-sectional view showing a configuration of a wiring substrate 20 according to an eleventh embodiment. FIG. 18 is a plan view of the transistor 230 shown in FIG. 17. An electronic device according to the present embodiment has the same configuration as that of the electronic device according to any one of the first to fifth and the eighth embodiments except for the configuration of the wiring substrate 20. FIGS. 17 and 18 show the same case as that of the first embodiment.

The wiring substrate 20 according to the present embodiment is the same as that of the first embodiment except for the planar shape of the transistor 230. The first wirings 232 of the transistor 230 have a comb-shaped planar layout. The source wirings 224 and the drain wirings 226 extend alternately over the regions of the semiconductor layer 236 sandwiched by the first wirings 232. A plurality of vias 223 is formed for one source wiring 224 and a plurality of vias 225 is formed for one drain wiring 226. The source wirings 224 and the drain wirings 226 also have a comb-shaped planar layout. In other words, the transistor 230 according to the present embodiment has a comb-shaped layout.

Also in the present embodiment, the same effects as those of the first embodiment can be obtained. Since the transistor 230 has a comb-shaped layout, it is possible to increase the on-state current of the transistor 230.

Although the embodiments of the present invention have been described with reference to the drawings, these are examples of the present invention, and various configurations other than those described above can be employed.

1. A semiconductor device comprising:
a wiring substrate; and
a semiconductor chip mounted over the wiring substrate,
wherein the wiring substrate includes
a core layer,
a first resin layer formed over the core layer, a first wiring formed over the core layer or over the first resin layer, and
a semiconductor layer formed over a layer of the core layer and the first resin layer, over which the first wiring is formed, and over the first wiring, and
wherein a semiconductor element is formed by the first wiring and the semiconductor layer.

2. The semiconductor device according to claim 1,
wherein the first wiring is formed over the core layer, and
the semiconductor device further includes
a second wiring formed over the first resin layer, and
a via which is formed in the first resin layer and which couples the semiconductor layer with the second wiring.

3. The semiconductor device according to claim 1,
wherein the first wiring is formed over the first resin layer, and
the semiconductor device further includes
a second resin layer formed over the first resin layer,
a second wiring formed over the second resin layer, and
a via which is formed in the second resin layer and which couples the semiconductor layer with the second wiring.

4. A semiconductor device comprising:
a wiring substrate; and
a semiconductor chip mounted over the wiring substrate,
wherein the wiring substrate includes
a semiconductor substrate,
a wiring layer formed over the semiconductor substrate,
a first wiring formed in the wiring layer, and
a semiconductor layer which is located over the wiring layer and which overlaps the first wiring in planar view, and
wherein a semiconductor element is formed by the first wiring and the semiconductor layer.

5. The semiconductor device according to claim 1,
wherein the semiconductor element is a transistor in which the first wiring is a gate electrode.

6. The semiconductor device according to claim 5,
wherein a source of the transistor is coupled to the semiconductor chip,
the wiring substrate includes a drain wiring for applying a first voltage to a drain of the transistor, and
a threshold voltage of the transistor is higher than the first voltage.

7. The semiconductor device according to claim 6,
wherein the first wiring is coupled to the semiconductor chip,
the wiring substrate includes a drain wiring for applying a first voltage to a drain of the transistor, and
a threshold voltage of the transistor is lower than the first voltage.

8. The semiconductor device according to claim 5,
wherein in planar view, a distance from the first wiring to the source of the transistor is larger than a distance from the first wiring to the drain of the transistor.

9. The semiconductor device according to claim 5, further comprising:
a storage element coupled to the transistor.

10. The semiconductor device according to claim 1, further comprising:
a gate insulating film formed between the semiconductor layer and the first wiring,
wherein the semiconductor element is a capacitive element in which the first wiring is a lower electrode and the semiconductor layer is an upper electrode.

11. The semiconductor device according to claim 1, further comprising:
a gate insulating film formed between the semiconductor layer and the first wiring,
wherein the semiconductor layer includes a source and a drain,
the source is short-circuited to the first electrode, and
the source, the drain, the gate insulating film, and the first electrode form a diode.

12. The semiconductor device according to claim 1,
wherein the semiconductor layer is an oxide semiconductor layer.

13. The semiconductor device according to claim 12,
wherein the oxide semiconductor layer is an InGaZnO layer, an InZnO layer, a ZnO layer, a ZnAlO layer, a ZnCuO layer, an NiO layer, an SnO layer, or a CuO layer.

14. The semiconductor device according to claim 1, further comprising:
a hard mask film which is formed over the semiconductor layer and which has the same planar shape as that of the semiconductor layer.

15. The semiconductor device according to claim 1,
wherein the wiring substrate includes a metal layer for heat radiation over a surface thereof.

16. An electronic device comprising:
a semiconductor device; and
a circuit substrate over which the semiconductor device is mounted,
wherein the semiconductor device includes
a wiring substrate, and
a semiconductor chip mounted over the wiring substrate,
wherein the wiring substrate has
a core layer,
a first resin layer formed over the core layer,
a first wiring formed over the core layer or over the first resin layer, and
a semiconductor layer formed over a layer of the core layer and the first resin layer, over which the first wiring is formed, and over the first wiring, and
wherein a semiconductor element is formed by the first wiring and the semiconductor layer.

17. An electronic device comprising:
a semiconductor device; and
a circuit substrate over which the semiconductor device is mounted,
wherein the semiconductor device includes
a wiring substrate, and
a semiconductor chip mounted over the wiring substrate,
wherein the wiring substrate has
a semiconductor substrate,
a wiring layer formed over the semiconductor substrate,
a first wiring formed over the wiring layer, and
a semiconductor layer which is located over the wiring layer and which overlaps the first wiring in planar view, and
wherein a semiconductor element is formed by the first wiring and the semiconductor layer.

18. A wiring substrate comprising:
a core layer;
a first resin layer formed over the core layer;
a first wiring formed over the core layer or over the first resin layer; and
a semiconductor layer formed over a layer of the core layer and the first resin layer, over which the first wiring is formed, and over the first wiring,
wherein a semiconductor element is formed by the first wiring and the semiconductor layer.

19. A wiring substrate comprising:
a semiconductor substrate;
a wiring layer formed over the semiconductor substrate;
a first wiring formed over the wiring layer; and
a semiconductor layer which is located over the wiring layer and which overlaps the first wiring in planar view,
wherein a semiconductor element is formed by the first wiring and the semiconductor layer.

20. A manufacturing method of a semiconductor device, the method comprising the step of:
mounting a semiconductor chip over a wiring substrate,
wherein the wiring substrate includes
a core layer,
a first resin layer formed over the core layer,
a first wiring formed over the core layer or over the first resin layer, and
a semiconductor layer formed over a layer of the core layer and the first resin layer, over which the first wiring is formed, and over the first wiring, and
wherein a semiconductor element is formed by the first wiring and the semiconductor layer.

21. A manufacturing method of a semiconductor device, the method comprising the step of:
mounting a semiconductor chip over a wiring substrate,
wherein the wiring substrate includes
a semiconductor substrate,
a wiring layer formed over the semiconductor substrate,
a first wiring formed over the wiring layer, and
a semiconductor layer which is located over the wiring layer and which overlaps the first wiring in planar view, and
wherein a semiconductor element is formed by the first wiring and the semiconductor layer.

22. A manufacturing method of a wiring substrate, the method comprising the steps of:
forming a core layer;
forming a first resin layer over the core layer; further
forming a first wiring over the core layer or over the first resin layer, and
forming a semiconductor layer over a layer of the core layer and the first resin layer, over which the first wiring is formed, and over the first wiring,
wherein a semiconductor element is formed by the first wiring and the semiconductor layer.

23. A manufacturing method of a wiring substrate, the method comprising the steps of:
forming a first wiring layer including a first wiring over a semiconductor substrate; and
forming a semiconductor layer that overlaps the first wiring in planar view over the first wiring layer,
wherein a semiconductor element is formed by the first wiring and the semiconductor layer.
